(19) United States
(12) Patent Application Publication
(10) Pub. No.: US 2014/0273463 A1
(43) Pub. Date: Sep. 18, 2014

(54) METHODS FOR FABRICATING INTEGRATED CIRCUITS THAT INCLUDE A SEALED SIDEWALL IN A POROUS LOW-K DIELECTRIC LAYER

(71) Applicant: GLOBALFOUNDRIES, INC., Grand Cayman (KY)

(72) Inventors: Denis Shamiryan, Dresden (DE); Adam Michal Urbanowicz, Dresden (DE)

(73) Assignee: GLOBALFOUNDRIES, Inc., Grand Cayman (KY)

(21) Appl. No.: 13/841,855

(22) Filed: Mar. 15, 2013

(51) Int. Cl. H01L 21/311

(52) U.S. Cl. CPC H01L 21/31116
USPC 438/696

(57) ABSTRACT

Methods for fabricating integrated circuits are provided. In one example, a method for fabricating an integrated circuit includes forming a sidewall in a porous low-k dielectric layer that overlies a semiconductor substrate using a plurality of discontinuous etching treatments. Exposed portions of the sidewall are progressively sealed interposingly between the discontinuous etching treatments to form a sealed sidewall. The sealed sidewall defines a trench in the porous low-k dielectric layer.

### TECHNICAL FIELD

The technical field relates generally to methods for fabricating integrated circuits, and more particularly relates to methods for fabricating integrated circuits including forming a sealed sidewall that defines a trench in a porous low-k dielectric layer.

### BACKGROUND

As the density of semiconductor devices increases and the size of circuit elements become smaller, the resistance capacitance (RC) delay time in back-end-of-line (BEOL) of integrated circuits increases and impacts circuit performance. To limit and/or reduce capacitance, porous dielectric materials having a low dielectric constant (low-k) are being used to replace traditional silicon-dioxide-based dielectric as an interlayer dielectric (ILD) material.

One challenge related to porous dielectric materials is their sensitivity to plasma etching used, for example, to form trenches (e.g., vias or other sidewall defined structures) into the porous material. In particular, the porous dielectric materials used for integrated circuits (e.g., the ILD layers) typically have open porosity of up to about 8 to 50 volume percent (vol. %) or greater and an average pore radius of from about 0.5 to about 2 nm. Radicals generated during plasma etching can readily penetrate into these open pores and damage the porous dielectric material. The damage is manifested as a localized increase in the k value (dielectric constant) of the porous dielectric material and consequently, the advantageous effect over silicon-dioxide-based dielectrics in reducing the capacitance is substantially reduced or lost. In a particular example, plasma damage to the porous dielectric material increases the k value resulting in an increase of capacitance of the porous dielectric material. The higher capacitance of the porous dielectric material embedded, for example, between copper wires (e.g., Damascene or Inlaid technology) increases RC delay of signals transmitted through the copper wires and this in turn affects overall performance of the integrated circuit. Current approaches to resolve this issue include sealing a trench's sidewall after complete formation of the trench in the porous dielectric material. Unfortunately, localized damage to the porous dielectric material may have already occurred after formation of the trench and therefore, sealing the sidewall after plasma etching is completed does not substantially limit and/or reduce capacitance of the integrated circuit.

Accordingly, it is desirable to provide methods for fabricating integrated circuits including forming a trench in a porous low-k dielectric layer using plasma etching, for example, in which damage to the porous low-k dielectric layer is limited, reduced, or eliminated to limit or reduce capacitance of the integrated circuit. Furthermore, other desirable features and characteristics of the present invention will become apparent from the subsequent detailed description and the appended claims, taken in conjunction with the accompanying drawings and this background.

### BRIEF SUMMARY

Methods for fabricating integrated circuits are provided herein. In accordance with an exemplary embodiment, a method for fabricating an integrated circuit includes forming a sidewall in a porous low-k dielectric layer that overlies a semiconductor substrate using a plurality of discontinuous etching treatments. Exposed portions of the sidewall are progressively sealed interposingly between the discontinuous etching treatments to form a sealed sidewall. The sealed sidewall defines a trench in the porous low-k dielectric layer.

In accordance with another exemplary embodiment, a method for fabricating an integrated circuit is provided. The method includes forming a porous low-k dielectric layer overlying a semiconductor substrate. The porous low-k dielectric layer is progressively etched using a plurality of discontinuous etching treatments to form a sidewall. Exposed portions of the sidewall are progressively sealed using a plurality of discontinuous sealing treatments that are correspondingly interposed between the discontinuous etching treatments to form a sealed sidewall. The sealed sidewall defines a trench in the porous low-k dielectric layer.

In accordance with another exemplary embodiment, a method for fabricating an integrated circuit is provided. The method includes forming a sealed sidewall that defines a trench in a porous low-k dielectric layer that overlies a semiconductor substrate. Forming the sealed sidewall includes etching an upper section of the porous low-k dielectric layer to form an upper portion of a sidewall. The upper portion of the sidewall is sealed to form a sealed upper portion. A deeper section of the porous low-k dielectric layer is etched to form a deeper portion of the sidewall that is disposed below the sealed upper portion. The deeper portion of the sidewall is sealed.

### BRIEF DESCRIPTION OF THE DRAWINGS

The various embodiments will hereinafter be described in conjunction with the following drawing figures, wherein like numerals denote like elements, and wherein:

FIGS. 1-6 illustrate, in cross-sectional views, an integrated circuit and methods for fabricating an integrated circuit in accordance with an exemplary embodiment.

### DETAILED DESCRIPTION

The following Detailed Description is merely exemplary in nature and is not intended to limit the various embodiments or the application and uses thereof. Furthermore, there is no intention to be bound by any theory presented in the preceding background or the following detailed description.

Various embodiments contemplated herein relate to methods for fabricating integrated circuits. Unlike the prior art, the exemplary embodiments taught herein form a sealed sidewall that defines a trench in a porous low-k dielectric layer using a plurality of alternating discontinuous etching and sealing treatments. In particular, the porous low-k dielectric layer is formed overlying a semiconductor substrate and is progressively etched using the plurality of discontinuous etching treatments, e.g., a series of discrete, short duration plasma etching treatments. The discontinuous etching treatments selectively remove sections of the porous low-k dielectric layer to expose portions of a sidewall in a stepwise fashion. As the portions of the sidewall become exposed, the portions are progressively sealed in a stepwise fashion using a plurality of discontinuous sealing treatments, e.g., a series of discrete, short duration plasma, ultraviolet light, or electron beam treatments that locally densify or seal the low-k dielectric material, correspondingly interposed between the discontinuous etching treatments to form the sealed sidewall and define the trench in the porous low-k layer. Because the sidewall is progressively sealed during formation of the trench, damage that might otherwise occur to the porous low-k dielectric layer during plasma etching of the trench is reduced and/or minimized. In particular, plasma damage to the porous low-k layer increases the dielectric constant resulting in an increase of capacitance of the low-k material. The higher capacitance of the low-k material embedded, for example, between copper wires increases RC delay of signals transmitted through the copper wires and this in turn affects overall performance of the integrated circuit. Furthermore, the plasma damage affects reliability of low-k material, resulting in faster dielectric breakdown. Thus, by reducing and/or minimizing damage to the low-k dielectric layer, many of the issues can be reduced, minimize, and/or avoided.

FIGS. 1-6 illustrate methods for fabricating an integrated circuit 10 in accordance with various embodiments. The described process steps, procedures, and materials are to be considered only as exemplary embodiments designed to illustrate to one of ordinary skill in the art methods for practicing the invention; the invention is not limited to these exemplary embodiments. Various steps in the manufacture of integrated circuits are well known and so, in the interest of brevity, many conventional steps will only be mentioned briefly herein or will be omitted entirely without providing the well-known process details.

FIG. 1 illustrates, in cross-sectional view, a portion of the integrated circuit 10 at an intermediate stage of fabrication in accordance with an exemplary embodiment. The integrated circuit 10 includes a semiconductor substrate 12 on which shallow trench isolation (STI) structures, source/drain regions, source/drain extension regions, gate dielectric, contacts, spacers, dummy gate patterns, hard masked layers, and other features may be formed. The semiconductor substrate 12 is typically a silicon wafer and includes various doping configurations as is known in the art. Alternatively, the semiconductor substrate 12 may include a compound semiconductor such as, silicon carbide, gallium arsenide, indium arsenide, or indium phosphide. Further, the semiconductor substrate 12 may include a silicon-on-isolator (SOI) structure.

A porous low-k dielectric layer 14 is formed overlying the semiconductor substrate 12. The porous low-k dielectric layer 14 is formed of a low-k dielectric material that is deposited overlying the semiconductor substrate 12 by chemical vapor deposition (CVD), high-density plasma CVD, spin-on, sputtering, or any other method known to those skilled in the art. In an exemplary embodiment, the low-k dielectric material includes an organic polymer, SiOF, SiOC, SiOCH, hydrogen silsesquioxane, and/or methyl silsesquioxane.

The dielectric constant of the porous low-k dielectric layer 14 is relatively low due at least in part to its relatively high free volume (e.g., open porosity). In particular, the porosity of the porous low-k dielectric layer 14 may be constitutive or subtractive. Constitutive porosity refers to the self-organization of the low-k dielectric material in which the material is porous without any additional treatment. Subtractive porosity involves selective removal of part of the low-k dielectric material. This can be achieved via an artificially added ingredient (e.g., a thermally degradable substance called a “porogen,” which is removed by annealing to leave behind pores) or by selectively etching (e.g., Si—O bonds in SiOCH materials removed by HF). In an exemplary embodiment, the porous low-k dielectric layer 14 has an open porosity of from about 15 to about 90 vol. %, an average pore radius of from about 0.5 to about 2 nm, and a dielectric constant of from about 1 to about 3, such as from about 1 to about 2.

As illustrated, the porous low-k dielectric layer 14 is formed as an interlayer dielectric (ILD) layer overlying the semiconductor substrate 12. In an exemplary embodiment, the porous low-k dielectric layer 14 has a thickness of from about 30 to about 500 nm.

A photoresist layer 16 is deposited overlying the porous low-k dielectric layer 14. Using well-known lithographical techniques, the photoresist layer 16 is patterned to form a patterned photoresist layer 18.

FIG. 2 illustrates, in cross-sectional view, the integrated circuit 10 at a further advanced fabrication stage in accordance with an exemplary embodiment. Using the patterned photoresist layer 18, an upper section 19 of the porous low-k dielectric layer 14 is selectively removed via a discontinuous etching treatment 20. In an exemplary embodiment, the discontinuous etching treatment 20 is a dry etching process. Non-limiting examples of the discontinuous etching treatment 20 include a plasma etching treatment using a gas, such as O₂, H₂, H₂O, H₂O₂, O₃, CO, CO₂, CF₄, CH₂F₂, C₄F₈, Ar, N₂, and/or SO₂, to form radicals for selectively removing the upper section 19 of the porous low-k dielectric layer 14. In an exemplary embodiment, the discontinuous etching treatment 20 is a discrete, short duration etching treatment with an exposure time of from about 0.5 to about 5 seconds, such as from about 0.5 to about 2 seconds, for example from about 1 to about 2 seconds.

As illustrated, the discontinuous etching treatment 20 forms an upper portion 22 of a sidewall 24 in the porous low-k dielectric layer 14. In an exemplary embodiment, the discontinuous etching treatment 20 selectively removes from about 1 to about 5 nm thickness of the upper section 19 to expose the upper portion 22 of the sidewall 24.

FIG. 3 illustrates, in cross-sectional view, the integrated circuit 10 at a further advanced fabrication stage in accordance with an exemplary embodiment. Using the patterned photoresist layer 18, the upper portion 22 of the sidewall 24 is sealed to form a sealed upper portion 26 via a discontinuous sealing treatment 28. In an exemplary embodiment, the discontinuous sealing treatment 28 is a plasma sealing treatment. Non-limiting examples of a plasma sealing treatment include a plasma treatment using a gas(es), such as He and/or NH₃, that forms radicals (or in the case of He emits extreme UV photons) that locally densify or seal the low-k dielectric material, for example, by locally collapsing the open pores proximate the upper portion 22 (e.g., depth of from about 0.1 to about 2 nm) of the sidewall 24. In an alternative embodiment, the discontinuous sealing treatment 28 is in ultraviolet light sealing treatment or an electron beam sealing treatment that, for example, locally collapses the open pores proximate the upper portion 22 of the sidewall 24 to locally densify or seal the low-k dielectric material. Alternatively, other treatments for sealing the low-k dielectric material may be used. In an exemplary embodiment, the discontinuous sealing treatment 28 is a discrete, short duration sealing treatment with an exposure time of from about 0.5 to about 5 seconds, such as from about 0.5 to about 2 seconds, for example from about 1 to about 2 seconds.

FIGS. 4-5 illustrate, in cross-sectional views, the integrated circuit 10 at further advanced fabrication stages in accordance with an exemplary embodiment. As illustrated in FIG. 4, using the patterned photoresist layer 18, a deeper section 30 of the porous low-k dielectric layer 14 is selectively removed via a second discontinuous etching treatment 32. In an exemplary embodiment, the second discontinuous etching treatment 32 is a dry etching process similar to the discontinuous etching treatment 20 as discussed above and is a discrete, short duration etching treatment with an exposure time of from about 0.5 to about 5 seconds, such as from about 0.5 to about 2 seconds, for example from about 1 to about 2 seconds.

As illustrated, the second discontinuous etching treatment 32 forms a deeper portion 34 of the sidewall 24 in the porous low-k dielectric layer 14 below the sealed upper portion 26. In an exemplary embodiment, the second discontinuous etching treatment 32 selectively removes from about 1 to about 5 nm thickness of the deeper section 30 to expose the deeper portion 34 of the sidewall 24.

Referring to FIG. 5, using the patterned photoresist layer 18, the deeper portion 34 of the sidewall 24 is sealed to form a sealed deeper portion 36 via a second discontinuous sealing treatment 38. In an exemplary embodiment, the second discontinuous sealing treatment 38 is a sealing treatment similar to the discontinuous sealing treatment 28 as discussed above with a relatively short duration exposure time of from about 0.5 to about 5 seconds, such as from about 0.5 to about 2 seconds, for example from about 1 to about 2 seconds.

FIG. 6 illustrates, in cross-sectional view, the integrated circuit 10 at a further advanced fabrication stage in accordance with an exemplary embodiment. Depending upon the desired depth of the sidewall 24 (e.g., from about 2 to about 500 nm), alternating additional discontinuous etching treatments 40 and additional sealing treatments 42 as discussed above in relation to discontinuous etching treatment 20, 32 and discontinuous sealing treatment 28, 38, respectively, can be used to progressively etch and seal the porous low-k dielectric layer 14 to form a sealed sidewall 44 that defines a trench 46. In an exemplary embodiment, about 2 to about 200 discontinuous etching treatments 20, 32, and 40 and about 2 to about 200 discontinuous sealing treatments 28, 38, and 42 are used to form the sealed sidewall 44.

Accordingly, methods for fabricating integrated circuits have been described. The exemplary embodiments taught herein form a sealed sidewall that defines a trench in a porous low-k dielectric layer using a plurality of alternating discontinuous etching and sealing treatments. The alternating discontinuous etching and sealing treatments progressively form the sealed sidewall during formation of the trench. As such, damage that might otherwise occur to the porous low-k dielectric layer during etching to form the trench is reduced and/or minimized to limit or reduce capacitance of the integrated circuit.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method for fabricating an integrated circuit comprising:
forming a sidewall in a porous low-k dielectric layer that overlies a semiconductor substrate using a plurality of discontinuous etching treatments; and
progressively sealing exposed portions of the sidewall interposingly between the discontinuous etching treatments to form a sealed sidewall that defines a trench in the porous low-k dielectric layer.

2. The method of claim 1, wherein forming the sidewall comprises providing the discontinuous etching treatments using a dry etching process.

3. The method of claim 2, wherein forming the sidewall comprises using the dry etching process comprising a plasma etching treatment.

4. The method of claim 3, wherein forming the sidewall comprises providing the plasma etching treatment using a gas comprising O₂, H₂, H₂O, H₂O₂, O₃, CO, CO₂, CF₄, CH₂F₂, C₄F₈, Ar, N₂, and/or SO₂.

5. The method of claim 1, wherein progressively sealing the exposed portions of the sidewall comprises using a plasma sealing treatment.

6. The method of claim 5, wherein progressively sealing the exposed portions of the sidewall comprises providing the plasma sealing treatment using a gas comprising He and/or NH₃.

7. The method of claim 1, wherein progressively sealing the exposed portions of the sidewall comprises using an ultraviolet light sealing treatment.

8. The method of claim 1, wherein progressively sealing the exposed portions of the sidewall comprises using an electron beam sealing treatment.

9. A method for fabricating an integrated circuit comprising:
forming a porous low-k dielectric layer overlying a semiconductor substrate;
progressively etching the porous low-k dielectric layer to form a sidewall using a plurality of discontinuous etching treatments; and
progressively sealing exposed portions of the sidewall using a plurality of discontinuous sealing treatments that are correspondingly interposed between the discontinuous etching treatments to form a sealed sidewall that defines a trench in the porous low-k dielectric layer.

10. The method of claim 9, wherein forming the porous low-k dielectric layer comprises depositing a low-k dielectric material overlying the semiconductor substrate, wherein the low-k dielectric material comprises an organic polymer, SiOF, SiOC, SiOCH, hydrogen silsesquioxane, and/or methyl silsesquioxane.

11. The method of claim 9, wherein forming the porous low-k dielectric layer comprises forming the porous low-k dielectric layer having a thickness of from about 30 to about 500 nm.

12. The method of claim 9, wherein progressively etching the porous low-k dielectric layer comprises exposing the porous low-k dielectric layer to each of the discontinuous etching treatments for a time of from about 0.5 to about 5 seconds.

13. The method of claim 9, wherein progressively sealing the exposed portions of the sidewall comprises exposing each of the exposed portions of the sidewall to a corresponding one of the discontinuous sealing treatments for a time of from about 0.5 to about 5 seconds.

14. The method of claim 9, further comprising:
depositing a photoresist layer overlying the porous low-k dielectric layer;
patterning the photoresist layer to form a patterned photoresist layer; and
using the patterned photoresist layer during progressively etching the porous low-k dielectric layer and progressively sealing the exposed portions of the sidewall to form the trench.

15. The method of claim 9, wherein progressively etching the porous low-k dielectric layer comprises providing from about 2 to about 200 discontinuous etching treatments to form the sidewall.

16. The method of claim 9, wherein progressively sealing the exposed portions of the sidewall comprises providing from about 2 to about 200 discontinuous sealing treatments to form the sealed sidewall.

17. A method for fabricating an integrated circuit comprising:
forming a sealed sidewall that defines a trench in a porous low-k dielectric layer that overlies a semiconductor substrate, wherein forming the sealed sidewall comprises:
etching an upper section of the porous low-k dielectric layer to form an upper portion of a sidewall;
sealing the upper portion of the sidewall to formed a sealed upper portion; and
etching a deeper section of the porous low-k dielectric layer to form a deeper portion of the sidewall that is disposed below the sealed upper portion.

18. The method of claim 17, wherein forming the sealed sidewall further comprises sealing the deeper portion of the sidewall.

19. The method of claim 17, wherein etching the upper section of the porous low-k dielectric layer comprises selectively removing from about 1 to about 5 nm thickness from the upper section of the porous low-k dielectric layer to form the upper portion of the sidewall.

20. The method of claim 17, wherein etching the deeper section of the porous low-k dielectric layer comprises selectively removing from about 1 to about 5 nm thickness from the deeper section of the porous low-k dielectric layer to form the deeper portion of the sidewall.
